(19) United States
(12) Patent Application Publication
(10) Pub. No.: US 2005/0048707 A1
(43) Pub. Date: Mar. 3, 2005

(54) Processing method for improving structure of a high voltage device

(76) Inventor: Jung-Cheng Kao, Shanghai (CN)

Correspondence Address: ROSENBERG, KLEIN & LEE, 3458 ELLICOTT CENTER DRIVE-SUITE 101, ELLICOTT CITY, MD, 21043, US

(21) Appl. No.: 10/922,856

(22) Filed: Aug. 23, 2004

(30) Foreign Application Priority Data
Sep. 1, 2003 (CN) 03150710.7

(51) Int. Cl. H01L 21/336; H01L 21/8234; H01L 21/76

(52) U.S. Cl. 438/197; 438/286; 438/299

(57) ABSTRACT

A processing method for improving a structure of a high voltage device utilizing a gradually reduced concentration between the drain region and the semiconductor substrate so as to reduce the intensity of the electric field to increase the breakdown voltage. A drift region is formed and forms a thin oxide layer and a patterned silicon nitride layer. A first patterned photo resistant is formed on the semiconductor substrate and the patterned silicon nitride layer is etched to define a field oxide region. A thermal process is utilized to form a field oxide layer and the silicon nitride layer and the thin oxide layer are removed. A gate oxide layer and a polysilicon gate structure are formed. A heavily ion dopant area is formed for use as a source/drain. A second patterned photo resistant is formed and used as a mask to form a dopant well area in the drift region.

### BACKGROUND OF THE INVENTION

1. Field of the Invention

The present invention generally relates to a processing method for forming a semiconductor device, and more particularly relates to a processing method for improving the structure of a high voltage device and the device characteristics of the high voltage device.

2. Description of the Prior Art

High voltage devices are applied to parts requiring high voltage operation in electronic products. Usually, in the architecture of integrated circuits, the control device of the I/O region of some products requires larger voltages than the control device of the key device region, so the I/O region must be provided with a device having a higher ability to bear high voltage so as not to cause a breakdown effect under normal operation with high voltage. Hence, the structure of the high voltage device is not similar to normal devices.

Referring to the FIG. 1, which is a drawing illustrating the structure of a conventional high voltage metal-oxide semiconductor (high voltage MOS). The steps of the formulation of the metal-oxide semiconductor device are as the following. First, in a P type semiconductor substrate 10, there is an N-drift region 12 of the high voltage device formed in the P type semiconductor substrate 10. Then, a field oxide layer 14 is deposited on the surface of the semiconductor substrate 10. Following, a gate structure 16 is formed on the surface of the surface of the field oxide layer 14, wherein the gate structure 16 comprises a gate oxide layer 162 and a polysilicon layer 164. Last, an ion implantation step is performed to form an N+ type dopant area in the semiconductor substrate 10 for using as a source 18 and a drain 20.

The high voltage device formed by using the prior method mentioned above, in the region near the A point of FIG. 1, where the formed drift region 12 is through the channel surface, the density of the electric field is higher and the potential is growing, so the depletion region formed by the drift region 12 can not resist the electric field of the high voltage and it easily causes early breakdown. In order to enhance the breakdown voltage, the traditional method reduces the dopant concentration of the drift region 12 so as to increase the width of the depletion region to achieve the purpose of increasing the breakdown voltage. However, when the dopant concentration of the drift region 12 is reduced, it will increase the resistance of the channel at this region and its on resistance will be increased to cause the decreasing of the current driving ability of the transistor device.

Therefore, in accordance with the problems mentioned above, the present invention provides a processing method for improving the structure of a high voltage device and the device characteristics of the high voltage device which overcomes the disadvantages of the conventional technology.

### SUMMARY OF THE INVENTION

The present invention provides a processing method for improving a structure of a high voltage device. The present invention utilizes the concentration, which is sequentially decreasing, between the drain region and the semiconductor substrate so as to reduce the intensity of the electric field to increase the breakdown voltage in order to improve the disadvantage of the early breakdown in the prior technology.

The present invention increases the drive current of the high voltage device to achieve the effect of improving the device characteristic so as to improve the disadvantage of the decreasing ability of the current driving in the prior technology.

In order to achieve previous objects, the present invention forms a drift region in a semiconductor substrate and forms a thin oxide layer and a patterned silicon nitride layer on the surface of the semiconductor substrate. The patterned silicon nitride layer is used as a mask to etch the semiconductor substrate so as to form a shallow trench therein and to fill an oxide into the shallow trench so as to form a shallow trench isolation structure. Then, a first patterned photo resistant is formed on the semiconductor substrate and using the first patterned photo resistant as a mask to etch the patterned silicon nitride layer to define a field oxide region and then to remove the first patterned photo resistant. Next, a thermal process is utilized to form a field oxide layer in the field oxide region and then removing the silicon nitride layer and the thin oxide layer. Following, a gate oxide layer and a polysilicon gate structure are sequentially formed on the semiconductor substrate. A heavily ion dopant area is formed in the semiconductor substrate for using as a source/drain. Then, a second patterned photo resistant is formed on the semiconductor substrate and using the second patterned photo resistant as a mask to form a dopant well area in the drift region; and the second patterned photo resistant is removed. Last, a thermal annealing/driving in step is performed on the semiconductor substrate.

Other advantages of the present invention will become apparent from the following description taken in conjunction with the accompanying drawings wherein are set forth, by way of illustration and example, certain embodiments of the present invention.

### BRIEF DESCRIPTION OF THE DRAWINGS

The foregoing aspects and many of the accompanying advantages of this invention will become more readily appreciated as the same becomes better understood by reference to the following detailed description, when taken in conjunction with the accompanying drawings, wherein:

FIG. 1 is an illustration showing a cross section of a high voltage metal-oxide-semiconductor device in accordance with the prior technology; and

FIG. 2a, FIG. 2b, FIG. 2c, FIG. 2d, FIG. 2e, FIG. 2f, FIG. 2g, and FIG. 2h are drawings illustrating a cross section of various steps of the formulation of the high voltage device in accordance with the present invention.

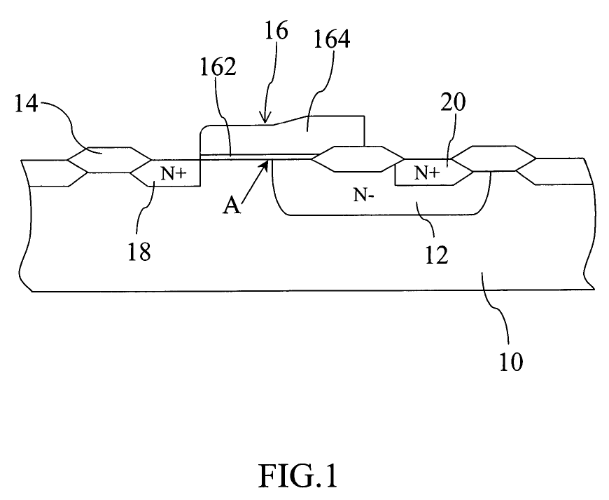

### DESCRIPTION OF THE PREFERRED EMBODIMENT

In the present invention, the concentration of the formed dopant area between the drain region and the semiconductor substrate is sequentially reduced. The highest concentration is adjacent the drain area. The distribution of the concentration decreases gradually. The concentration is lowest at the area close to the semiconductor substrate and the concentration of this area is equal to the drift region. The present invention utilizes this improved structure of the high voltage device to simultaneously increase the breakdown voltage and the driving current.

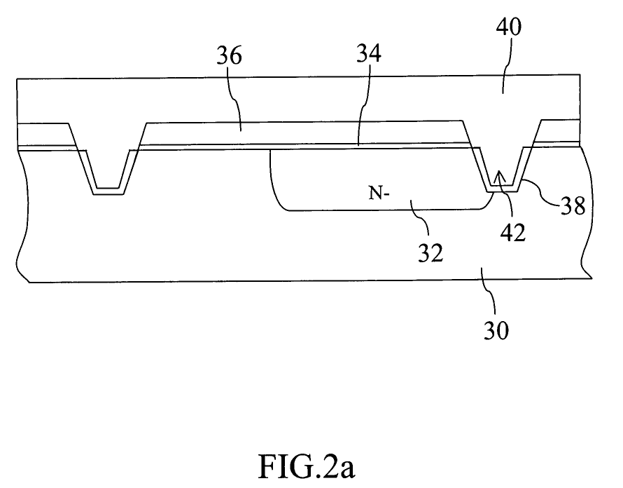

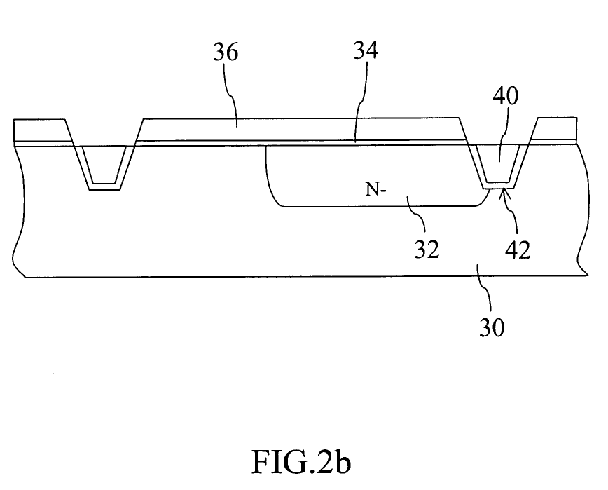

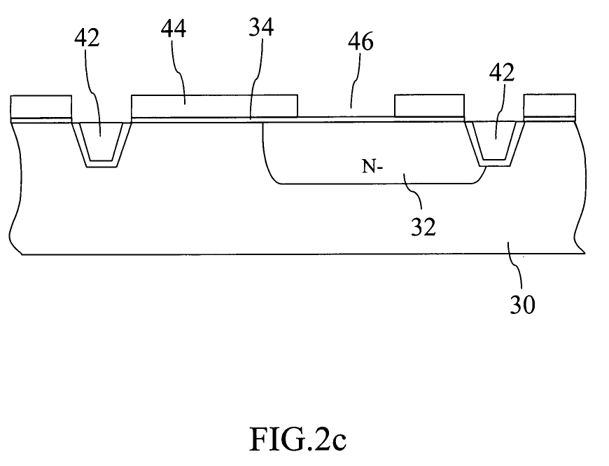

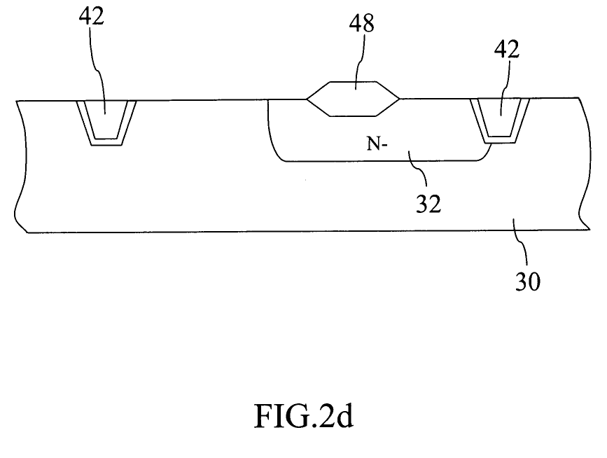

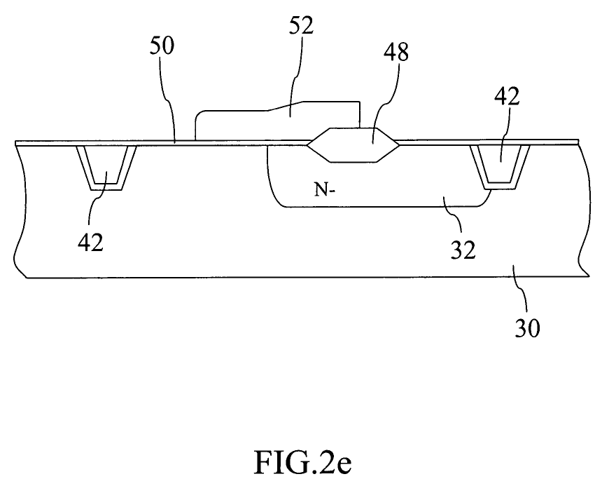

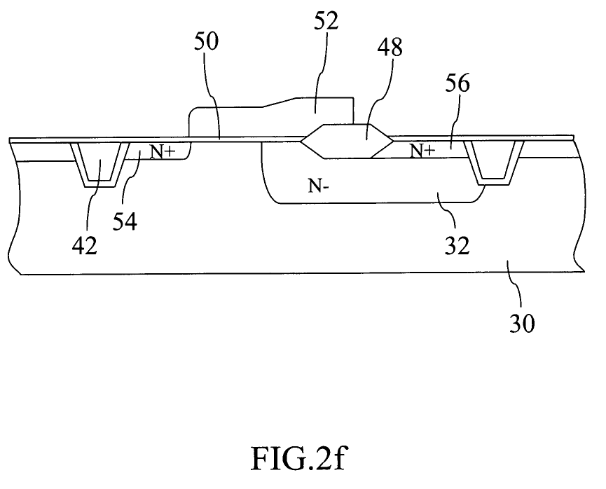

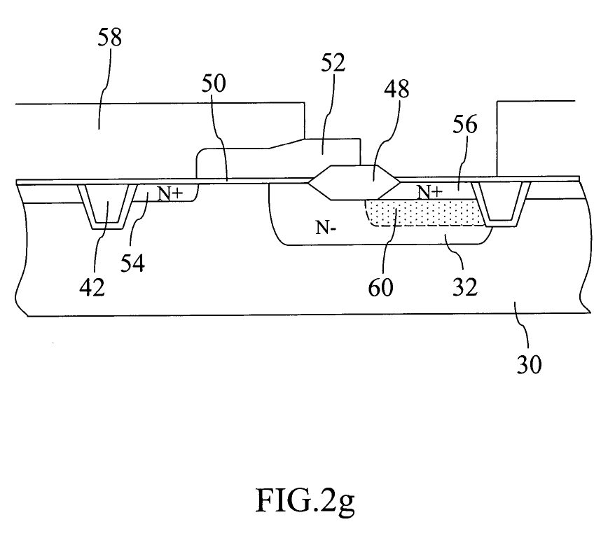

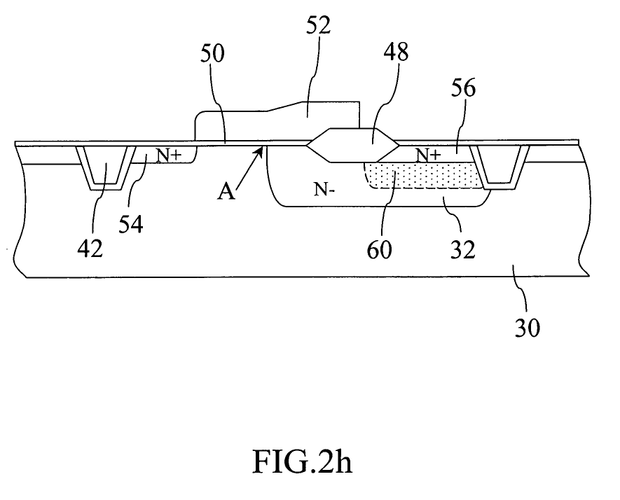

FIG. 2a through FIG. 2h are drawings illustrating cross sections of various steps of the formulation of the high voltage device in accordance with an embodiment of the present invention. Such as shown in the figures, the process of the present invention includes the following steps. First, a P type semiconductor substrate 30 is provided. Referring to FIG. 2a, an N type lightly dopant well area is formed in the semiconductor substrate 30 by using an ion implantation step and the N type lightly dopant well area is used for a N-drift region 32 of the high voltage device. Wherein the N-drift region 32 is formed by utilizing a energy of about 100 to 180 KeV to implant the N type dopant, such as phosphorous (P) ions, into the semiconductor substrate 30 and driving in the phosphorous ion dopant into the semiconductor substrate 30 by a thermal process so as to form the N-drift region 32 having a concentration of phosphorous ion dopant of the N-drift region of between 1*10¹² per cm² to 5*10¹³ per cm².

Next, referring to FIG. 2a, the present invention utilizes chemical vapor deposition (CVD) technology to sequentially deposit a thin oxide layer 34 and a patterned silicon nitride layer 36 on the surface of the semiconductor substrate 30. Wherein, the formulation of the patterned silicon nitride layer 36 utilizes a patterned photo resistant covering the surface of a silicon nitride layer and then uses the patterned photo resistant as a mask to etch and remove a portion of the silicon nitride layer so as to form the patterned silicon nitride layer 36, and, last, to remove the patterned photo resistant.

Then, the patterned silicon nitride layer 36 is used as a mask to etch and to remove the exposed semiconductor substrate 30 so as to form a plurality of shallow trenches 38, such as shown in the FIG. 2a. Next, chemical vapor deposition technology is utilized to deposit an oxide layer 40 to fill those shallow trenches 38 so as to form a shallow trench isolation (STI) structure 42. Then, chemical mechanical polishing (CMP) technology is utilized to perform a polishing step to polish the oxide layer 40 to the patterned silicon nitride layer 36, such as shown in the FIG. 2b.

Following, a photolithography and etching process is utilized to form a first patterned photo resistant, which is not shown in the figure, on the semiconductor substrate 30. The first patterned photo resistant is used as a mask to dry etch and remove a portion of the patterned silicon nitride layer 36 to form the patterned silicon nitride layer 44 as shown in the FIG. 2c so as to define a field oxide region 46 and, then, to remove the first patterned photo resistant.

The present invention utilizes a thermal process to form a field oxide (FOX) layer 48 in the field oxide region 46, such as shown in the FIG. 2d. After forming the field oxide (FOX) layer 48, a wet etching step is utilized to remove the patterned silicon nitride layer 44 and the thin oxide layer 34.

Referring to FIG. 2e, first, a gate oxide layer 50 is grown on the surface of the semiconductor substrate 30. Then, a polysilicon layer 52 is deposited on the gate oxide layer 50. Next, a patterned photo resist is utilized to etch and to define the polysilicon layer 52 so as to form a gate structure provided with a polysilicon layer 52 and the gate oxide layer 50 there below.

Then, a heavily ion implantation step is performed in the semiconductor substrate 30 at lateral sides of the polysilicon layer 52 to form an N type heavily ion dopant area in the semiconductor substrate 30 for use as a source 54 and a drain 56, such as shown in the FIG. 2f.

A photolithography and etching process are utilized to form a second patterned photo resistant 58 on the semiconductor substrate 30. Referring to FIG. 2g, the second patterned photo resistant 58 is used as a mask to perform the ion implantation step in the semiconductor substrate 30 so as to form a N-type dopant well area 60 within the drift region 32 and under the drain 56. At this time, a concentration of the dopant of the drain 56 is larger than a concentration of the dopant of the N-type dopant well area 60, and wherein the concentration of the dopant of the N-type dopant well area 60 is larger than a concentration of the dopant of the drift region 32.

After the formulation of the N-type dopant well area 60, the second patterned photo resistant 58 is removed by etching, such as shown the FIG. 2h. Last, a thermal annealing/driving in step is performed on the semiconductor substrate 30 so as to adjust the concentration distribution and to repair the lattice structure at the ion-striking region via this step.

To sum up the forgoing, in the structure of the high voltage device formed in accordance with the present invention, the concentration of the drift region 32 under the field oxide layer 48 is lighter than the normal dopant area. However, in the present invention, between the drain 56 and the semiconductor substrate 30, it forms a multi heavily/lightly dopant area, such as the N-type lightly dopant area 32 (drift region) and the N-type dopant area 60, wherein the concentration of the dopant of the N-type heavily dopant area 56 (the drain) is larger than the concentration of the dopant of the N-type dopant well area 60 and larger than the concentration of the dopant of the drift region 32. Hence, the position near the conjunction, as the A point of the FIG. 2h, does not suffer from potential crowding so as to increase the breakdown voltage. Furthermore, the concentration of the dopant near the drain is not too low so as to improve the current driving ability of the high voltage transistor.

On the other hand, the process of the present invention can be successfully integrated in deep sub-micron processing using the shallow trench isolation structure. Because the formulation of the N type dopant area is isolated by the shallow trench isolation structure, the present invention will not cause short effects between the active areas.

The forgoing description of the embodiments of the invention has been presented for purposes of illustration and description, and is not intended to be exhaustive or to limit the present invention to he precise from disclosed. The description was selected to best explain the principles of the invention and practical application of these principles to enable others skilled in the art to best utilize the invention in various embodiments and modifications as are suited to the particular use contemplated. It is intended that the scope of the invention not to be limited by the specification, but be defined by the claim set forth below.

1. A processing method for improving a structure of a high voltage device comprising:
providing a semiconductor substrate, wherein a drift region formed in the semiconductor substrate;
forming a thin oxide layer and a patterned silicon nitride layer on the semiconductor substrate;
using the patterned silicon nitride layer as a mask to etch the semiconductor substrate so as to form a shallow trench therein and to fill an oxide into the shallow trench so as to form a shallow trench isolation structure;
forming a first patterned photo resistant on the semiconductor substrate and using the first patterned photo resistant as a mask to etch the patterned silicon nitride layer to define a field oxide region and then to remove the first patterned photo resistant;
utilizing a thermal process to form an field oxide layer in the field oxide region and then removing the silicon nitride layer and the thin oxide layer;
sequentially forming a gate oxide layer and a polysilicon gate structure on the semiconductor substrate;
forming a heavily ion dopant area in the semiconductor substrate for use as a source/drain;
forming a second patterned photo resistant on the semiconductor substrate and using the second patterned photo resistant as a mask to form a dopant well area in the drift region; and
removing the second patterned photo resistant and performing a thermal annealing/driving in step on the semiconductor substrate.

2. The processing method for improving a structure of a high voltage device according to claim 1, wherein the drift region is an N type lightly dopant well area.

3. The processing method for improving a structure of a high voltage device according to claim 1, wherein the drift region is formed by utilizing an energy of about 100 to 180 KeV to implant the N type dopant, such as phosphorous ions, into the semiconductor substrate and driving in the dopant using a thermal process.

4. The processing method for improving a structure of a high voltage device according to claim 1, wherein a concentration of the ion dopant of the drift region is between 1*10¹² per cm² to 5*10¹³ per cm².

5. The processing method for improving a structure of a high voltage device according to claim 1, wherein the step of filling the oxide into the shallow trench utilizes chemical vapor deposition technology.

6. The processing method for improving a structure of a high voltage device according to claim 1, wherein the step of removing the silicon nitride layer and the thin oxide layer utilizes a wet etching method.

7. The processing method for improving a structure of a high voltage device according to claim 1, further comprising after the step of depositing the oxide, polishing the oxide to stop at the patterned silicon nitride layer.

8. The processing method for improving a structure of a high voltage device according to claim 7, wherein the step of polishing the oxide utilizes chemical mechanical polishing technology.

9. The processing method for improving a structure of a high voltage device according to claim 1, wherein the method for forming the patterned silicon nitride layer comprises:
depositing a silicon nitride layer on the semiconductor substrate;
forming a patterned photo resistant layer on a surface of the silicon nitride layer; and
using the patterned photo resistant layer as a mask to etch the silicon nitride layer to form the patterned silicon nitride layer and then removing the patterned photo resistant layer.

10. The processing method for improving a structure of a high voltage device according to claim 1, wherein a dopant concentration of the heavily ion dopant area is larger than a dopant concentration of the dopant well area, and a dopant concentration of the dopant well area is larger than a dopant concentration of the drift region.
